(19) United States
(12) Patent Application Publication
(10) Pub. No.: US 2005/0139846 A1
(43) Pub. Date: Jun. 30, 2005

(54) High power light emitting diode package and fabrication method thereof

(76) Inventors: Jung Kyu Park, Suwon (KR); Chan Wang Park, Sungnam (KR); Joon Ho Yoon, Seoul (KR); Chang Wook Kim, Anyang (KR); Young Sam Park, Seoul (KR)

Correspondence Address: LOWE HAUPTMAN GILMAN AND BERNER, LLP, 1700 DIAGONAL ROAD, SUITE 300 /310, ALEXANDRIA, VA, 22314, US

(21) Appl. No.: 10/859,144

(22) Filed: Jun. 3, 2004

(30) Foreign Application Priority Data
Dec. 26, 2003 (KR) 2003-97218

(51) Int. Cl. H01L 33/00; H01L 21/00

(52) U.S. Cl. 257/98; 257/99; 257/100; 438/22; 438/25

(57) ABSTRACT

Disclosed is a high power LED package. In the LED package, a lower board has a heat radiation member in an LED mounting area and at least one via hole around the heat radiation member. First and second bottom electrodes are formed in the underside of the lower board, and connected to the heat radiation member and the via hole. An insulation layer is formed on the lower board to cover the heat radiation member. First and second electrode patterns on the insulation layer are connected to the first and second bottom electrodes through the via hole.

### BACKGROUND OF THE INVENTION

1. Field of the Invention

The present invention relates to a light emitting diode package, and more particularly, a high power light emitting diode package which can enhance heat radiation effect as well as omit a wire bonding procedure to simplify a package structure and reduce the package size.

2. Description of the Related Art

Light Emitting Diodes (LEDs) are widely used owing to several advantages such as low power consumption and high brightness, and in particular, recently utilized in illumination devices and as backlights for large-sized Liquid Crystal Displays (LCDs). The LEDs are provided in the form of packages to be easily mounted on the illumination devices and so on. LED protection ability, connection structures to main devices and heat radiation performance for radiating heat generated from LEDs are main bench-marks of the LED packages. High heat radiation performance is a more important package requirement in an industrial field such as common illumination devices and LCD backlights which adopt high power LEDs. FIG. 1a is a perspective sectional view illustrating a conventional high power LED package.

Referring to FIG. 1a, an LED package 10 includes a housing 1 having lead frames 2, an LED 3 in the form of a chip, a heat sink 4 seating the LED 3 thereon, a silicon sealant 5 for sealing the LED 3 and a plastic lens 7 for covering the silicon sealant 5. The LED 3 is connected to the lead frames 2 via wires 6 to be powered, and seated on the heat sink 4 via solders.

The LED package 10 in FIG. 1a is mounted on a PCB 9, as shown in FIG. 1b, of an illumination device (not shown). The heat sink 4 of the LED package 10 can transfer heat generated from the LED 3 to the PCB 9 via a heat conductive pad 8 such as solders to suitably radiate the heat to the outside.

Fabrication of the high power LED package is difficult owing to a complicated process such as a die bonding and a wire bonding of the LED. In particular, its assembly/connection process such as wire bonding may have a high percent defective, and the wires may act as a factor for increasing the size of the overall package.

FIGS. 2a and 2b illustrate another conventional high power LED package.

Referring to FIGS. 2a and 2b, a high power LED package 20 includes a lower ceramic board 11 having lead frames 13 and 14 and an upper ceramic board 12 having a circular cavity therein. On the lower ceramic board 11, there is mounted an LED 15 to be connected to the lead frames 13 and 14. A cylindrical reflector 12a is placed on the side wall of the cavity in the upper ceramic board 12, and transparent resin is filled into the cavity to encapsulate the LED 15.

Unlike FIG. 1a, one electrode of the LED 15 in the LED package 20 shown in FIG. 2a is connected to one of the lead frames 13 and 14 via a wire 16. Alternatively, the LED 15 may be mounted via flip chip bonding.

Since the overall structure is simplified, there are advantages that a fabrication process is facilitated and percent defective is reduced, but heat radiation effect is degraded as a drawback.

More particularly, although the package shown in FIG. 2a may also have a plurality of conductive via holes (not shown) formed in the lower ceramic board 11 to promote heat radiation from the LED 15, the size and number of the conductive via holes is essentially restricted to stably support an LED chip while preventing unwanted contact with the lead frames As a consequence, the LED package has a relatively lower heat radiation effect than that of the package in FIG. 1a, and thus cannot sufficiently endure the heat generated from the high power LED.

As described above, the conventional LED package tends to be defective owing to its complicated structure and fabrication process. To the contrary, the package of a simple structure has a problem that heat radiation effect, which is one of its major functions, is degraded.

### SUMMARY OF THE INVENTION

Therefore the present invention has been made to solve the foregoing problems of the prior art.

It is an object of the present invention to provide a novel LED package having a simplified overall structure to facilitate its fabrication as well as more effectively radiate heat generated from an LED therein.

It is another object of the present invention to provide a fabrication method of the LED package of the invention.

According to an aspect of the invention for realizing the object, there is provided an LED package comprising: a lower board having a heat radiation member formed in an LED mounting area and filled with conductive material and at least one via hole formed around the heat radiation member; first and second bottom electrodes formed in the underside of the lower board and connected to the heat radiation member and the at least one conductive via hole, respectively; an insulation layer formed on the top of the lower board to cover at least the heat radiation member; first and second electrode patterns formed on the insulation layer and connected to the first and second bottom electrodes through the at least one conductive via hole, respectively; and an LED connected to the first and second electrode patterns.

Preferably, the LED may be connected to the first and second electrode patterns via flip chip bonding.

The present invention can realize various forms of vertical connection structures between the first and second electrode patterns and the first and second bottom electrodes.

According to another aspect of the present invention, the at least one conductive via hole may comprise first and second conductive via holes arranged in opposite positions around the heat radiation member, and wherein the first and second electrode patterns may be connected to the first and second bottom electrodes through the first and second conductive via holes, respectively. Further, the first and second conductive via holes may be provided in plurality, respectively.

According to an further another aspect of the present invention, the first electrode pattern may be connected to the first bottom electrode via the at least one conductive via hole, and the second electrode pattern may be connected to the second bottom electrode via the heat radiation member.

Preferably, one of the first and second electrodes may be leaded to the heat radiation member to more effectively induce heat radiation.

According to an further another aspect of the present invention, the heat radiation member has a sectional area matching at least 50% of that of the LED, and the heat radiation member has a sectional area larger than that of the LED.

Preferably, the insulation layer may have a thickness of about 100 μm or less so that heat can be effectively radiated through the heat radiation member.

Preferably, The LED package may further comprise an upper board formed on the lower board to surround the LED. In this embodiment, the upper board may have a reflector provided in an inside wall portion surrounding the LED, and the LED package of the invention may further comprise a transparent lens structure provided on the upper board.

According to still another aspect of the invention for realizing the object, there is provided a fabrication method of LED packages comprising the following methods of: preparing a lower board having a heat radiation member formed in an LED mounting area filled with conductive material and an at least one conductive via hole formed around the heat radiation member; forming an insulation layer on the top of the lower board to cover at least the heat radiation member; forming first and second bottom electrodes in the underside of the lower board to be connected to the heat radiation member or the at least one conductive via hole; forming first and second electrode patterns on the insulation layer to be connected to the first and second bottom electrodes through the heat radiation member or the at least one conductive via hole, respectively; and mounting an LED to be connected to the first and second electrode patterns.

As set forth above, the present invention proposes an approach of mounting the LED via flip chip bonding instead of wire bonding that is a main factor causing a complicated structure and assembly process as well as defects. Further, the present invention provides a novel structure capable of enhancing heat radiation effect while utilizing flip chip bonding LED.

In order to form an electrode connection structure together with a heat radiation structure filled with high heat conductivity metal in a flip chip mounting area, the present invention also proposes to provide a large area heat radiation member, cover the heat radiation member with an insulation layer, and then form electrode patterns necessary for flip chip bonding on the insulation layer.

### BRIEF DESCRIPTION OF THE DRAWINGS

FIGS. 1a and 1b are perspective sectional and side sectional views illustrating a conventional high power LED package;

FIGS. 2a and 2b are side sectional and perspective views illustrating another conventional high power LED package;

FIG. 3 is a sectional view illustrating a high power LED package according to a preferred embodiment of the invention;

FIG. 4 is a sectional view illustrating a high power LED package according to an alternative embodiment of the invention;

FIGS. 5a to 5i are perspective views illustrating a fabrication process of high power LED packages according to the invention;

FIG. 6 is a perspective view illustrating a lower board having a plurality of conductive via holes according to the invention; and

FIGS. 7a and 7b are perspective views illustrating a heat radiation member structure according to the invention.

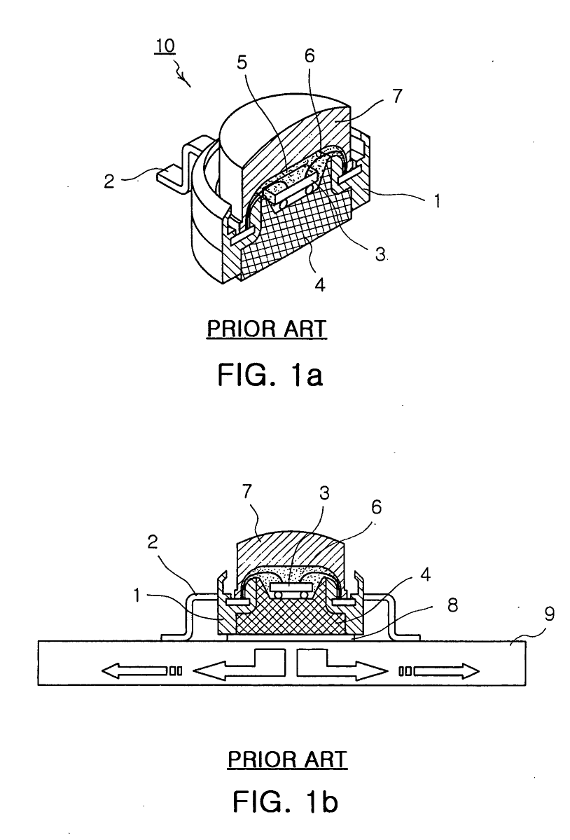

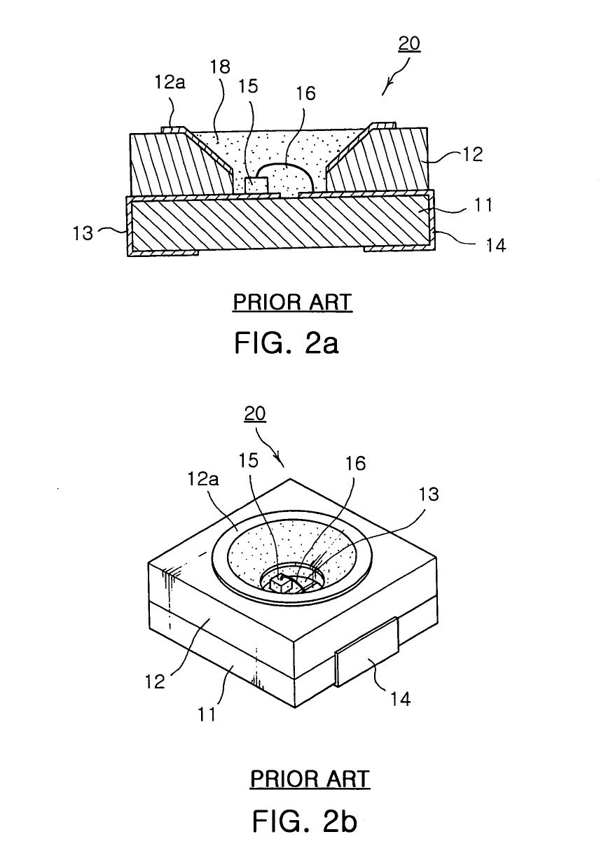

### DETAILED DESCRIPTION OF THE PREFERRED EMBODIMENT

Preferred embodiments of the present invention will now be described in detail with reference to the accompanying drawings.

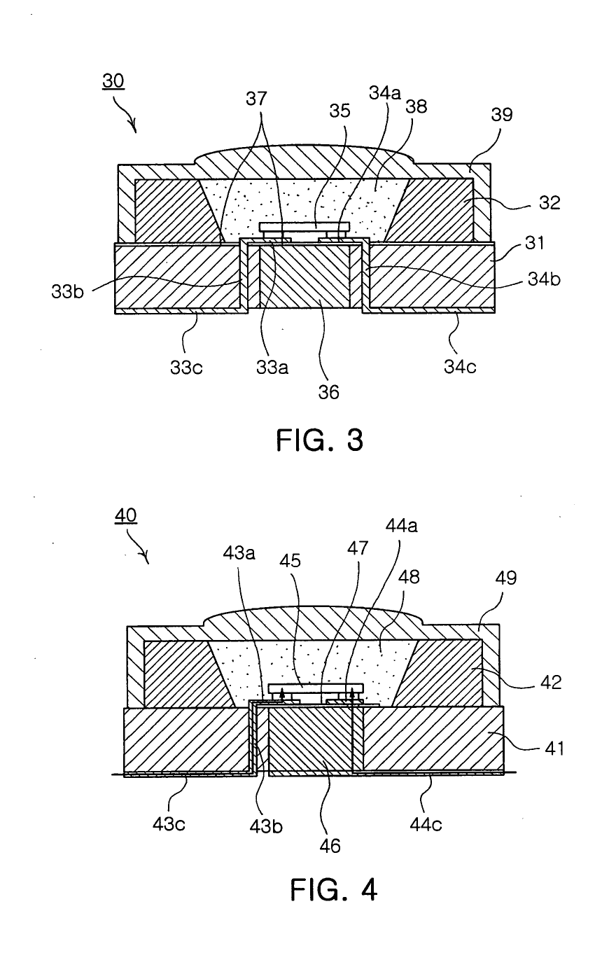

FIG. 3 is a sectional view illustrating a high power LED package according to a preferred embodiment of the invention.

Referring to FIG. 3, a high power LED package 30 includes a lower board 31 mounted with an LED 35 and an upper board 32 surrounding an area where the LED 35 is arranged.

The lower board 31 includes a heat radiation member 36 formed in a substantially central area and first and second conductive via holes 33b and 34b defining two vertical connection structures. Unlike the conductive via holes 33b and 34b of tens μm sizes, the heat radiation member 36 has a size corresponding to the that of the LED 35. The heat radiation member 36 can be made by filling conductive material into a cavity of a sufficient size formed in the lower board 31. The heat radiation member 36 has a sectional area preferably matching about 50% of that of the LED 35 to be mounted thereon, and more preferably larger than that of the LED 35.

The lower board 31 is covered with an insulation layer 37, which is sized to cover at least the heat radiation member 36. On the insulation layer 37, first and second electrode patterns 33a and 34a are formed to be connected to the first and second conductive via holes 33b and 34b, respectively. The insulation layer 37 functions to separate the electrode patterns for flip chip bonding from the filling material of the heat radiation member (e.g., mainly a conductive material such as metal). The insulation layer 37 is preferably formed at a thickness of about 100 μm not to excessively block the heat transfer from the LED to the heat radiation member by large quantities.

The LED 35 is so mounted that the electrodes thereof are connected to the first and second electrode patterns 33a and 34a via flip chip bonding. The first and second conductive via holes 33b and 34b are connected to first and second bottom electrodes 33c and 34c, respectively, and the first and second bottom electrodes 33c and 34c function as power supplying terminals of the LED package 30.

In addition, transparent resin may be filled into the inner mounting area of the upper board to encapsulate the LED, and a transparent lens structure 39 may be mounted on the upper board 32 to more efficiently emit light generated from the LED 35.

FIG. 4 is a sectional view illustrating a high power LED package according to an alternative embodiment of the invention. The LED package of this embodiment shown in FIG. 4 has a configuration similar to that shown in FIG. 3 except for vertical connection structures between LED mounting electrodes and power supplying electrodes.

Referring to FIG. 4, the LED package 40 includes a lower board 41 mounted with an LED 45 and an upper board 32 for surrounding an area where the LED 45 is placed. In addition, a transparent lens structure 49 may be mounted on the upper board 42 to efficiently emit light generated from the LED 45.

The lower board 41 includes a heat radiation member 46 formed in a substantially central area and a conductive via hole 43b. The heat radiation member 46 can be made by filling conductive material into a cavity of a sufficient size formed in the lower board 41. The heat radiation member 46 has a sectional area preferably matching about 50% of that of the LED 45 to be mounted thereon, and more preferably larger than that of the LED 45.

On the lower board 41, there is arranged an insulation layer 47, which is sized to cover the heat radiation member 46. On the insulation layer 47, there are formed first and second electrode patterns 43a and 44a.

The first electrode pattern 43a is connected to the conductive via hole 43b as in the embodiment shown in FIG. 3, whereas the second electrode pattern 44a is connected to the heat radiation member 46. Therefore, this embodiment provides the conductive via hole 43b as means for connecting the first electrode pattern 43a to the first bottom electrode 43c. Then, the heat radiation member 46 of this embodiment also functions as vertical connecting means together with heat radiating means. Further, in this embodiment, the second bottom electrode 44c is leaded to the heat radiation member 46 to enhance heat radiation effect, and this structure can be similarly applied to the embodiment in FIG. 3.

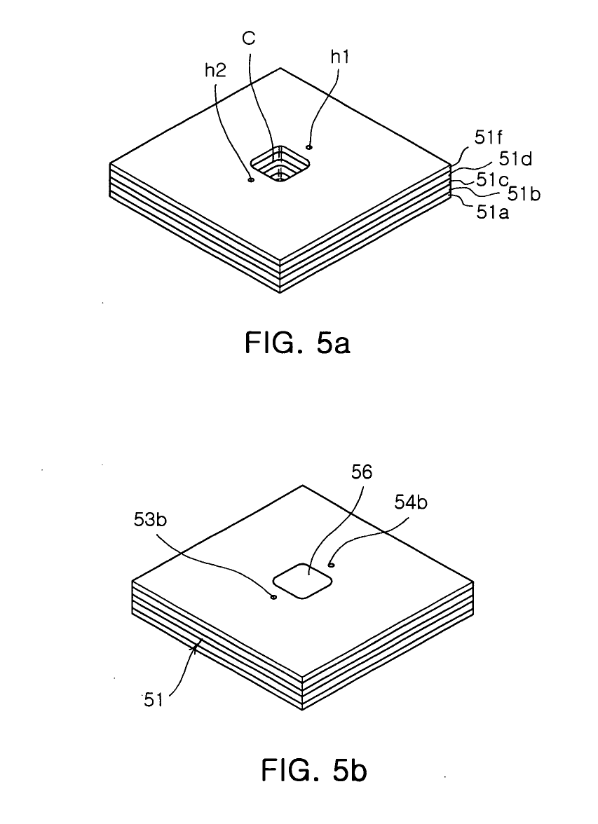

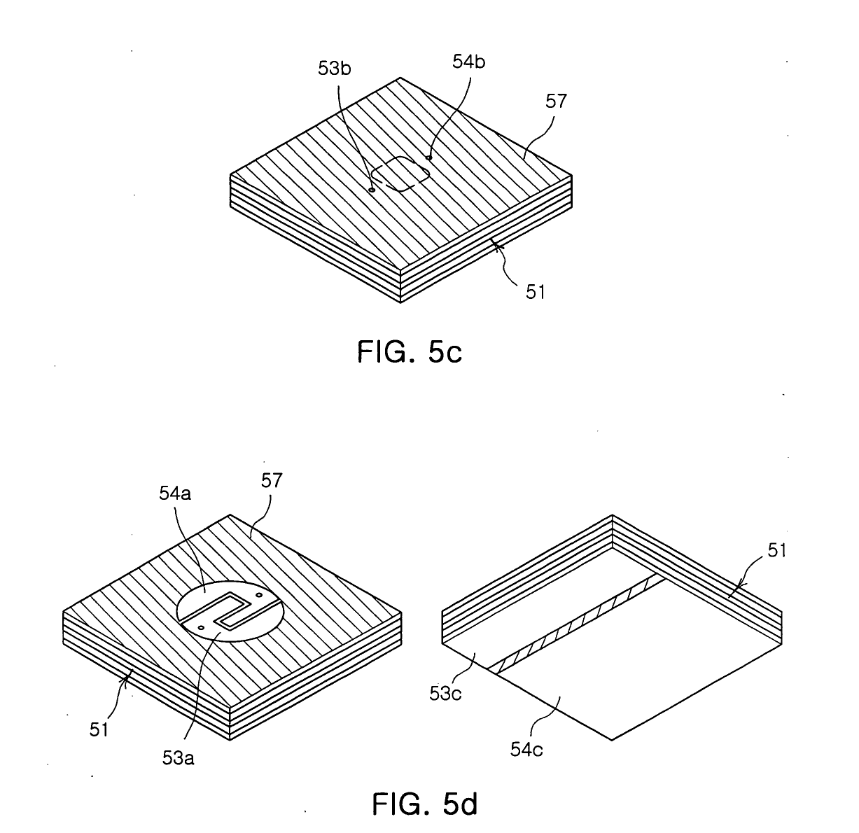

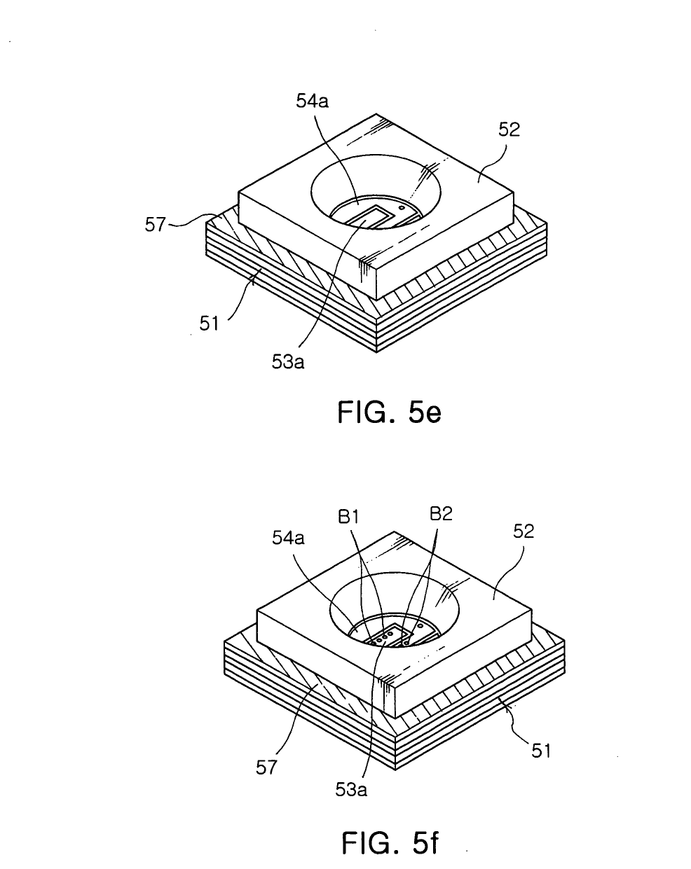

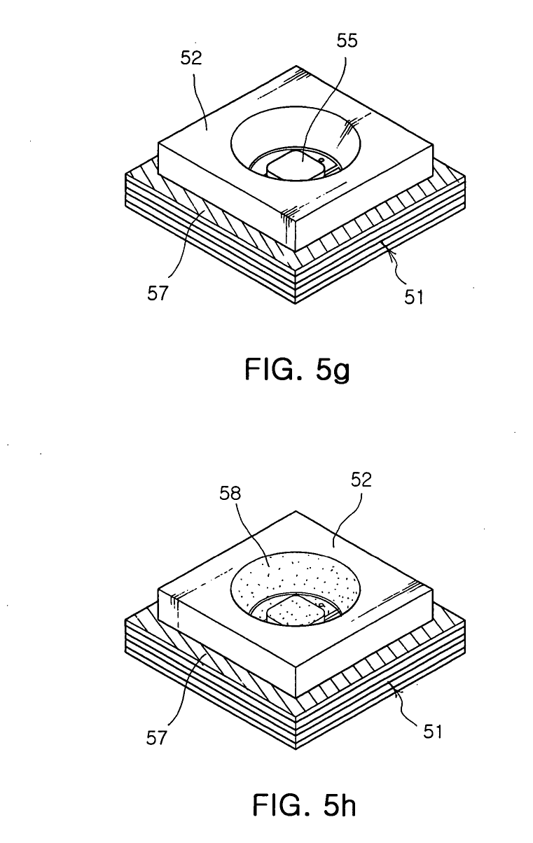

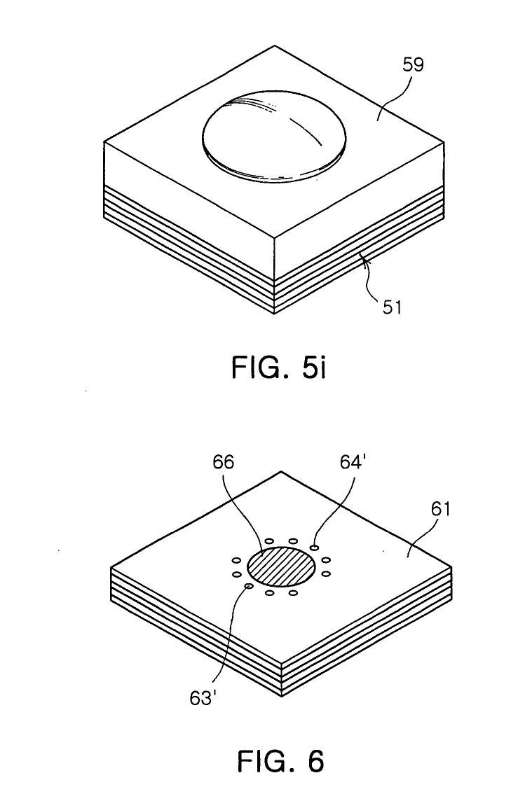

FIGS. 5a to 5i are perspective views illustrating a fabrication process of high power LED packages according to the invention.

As shown in FIG. 5a, a lower board 51 having a cavity C in a substantially central area and two via holes h1 and h2 formed around the cavity C is prepared. The lower board can be produced by laminating a plurality of green sheets for example 5 green sheets 51a to 51e as in this embodiment according to Low Temperature Cofired Ceramic (LTCC) technique or High Temperature Cofired Ceramic (HTCC) technique. While the lower board 51 is made of ceramic like this, it may be made of a PCB or other insulating material. The cavity C has a sectional area preferably matching about 50% of that of the mounted LED.

Then, as shown in FIG. 5b, suitable conductive material is filled into the cavity C to form a heat radiation member 56, and into the via holes h1 and h2 formed in the lower board 51 to form conductive via holes 53b and 54b. Since the high heat conductivity material filling the heat radiation member 56 generally has a predetermined value of electric conductivity, the heat radiation member 56 can be formed through the same procedure as the filling procedure of the conductive via holes 53b and 54b. This is a printing procedure using metal paste, and more particularly, may be realized as a printing procedure for the respective green sheets 51a to 51e in the lamination procedure shown in FIG. 5a.

Next an insulation layer 57 is formed on the lower board 51 as shown in FIG. 5c. The insulation layer 57 is a constitutional element for forming electrode patterns for flip chip bonding as well as insulating the large-sized heat radiation member 56 arranged in a mounting area, and thus so formed to cover the area of the heat radiation member 56. The insulation layer is preferably made at a thickness of about 100 μm or less. The insulation layer can be made through a conventional process such as lamination, spraying or printing, and for the purpose of stabilization, may be sintered after being laid on the lower board.

Then, electrodes are formed on the top and underside of the lower board 51 as shown in FIG. 5d. On the insulation layer 57, first and second electrode patterns 53a and 54a are first formed to be connected to the two conductive via holes 53b and 54b, respectively. Then, first and second bottom electrodes 53c and 54c are formed on the underside of the lower board 51 to be connected to the two conductive via holes 53b and 54b, respectively. The second bottom electrode 54c is leaded to the heat radiation member 56. This electrode forming procedure can be implemented through a procedure such as printing, plating, vacuum deposition, sputtering or post-deposition photolithography, and sintering may be selectively added to stabilize the electrodes formed like this.

Next, as shown in FIG. 5e, an upper board 52 having a cavity for surrounding the LED-mounting area is mounted on the lower board 51. The upper board is not limited in its material, but may be made of metal, ceramic and/or plastic. Preferably, a reflector may be additionally formed on the inside wall of the cavity to improve reflectivity. Further, the upper board-mounting procedure may be alternatively performed following an LED-mounting procedure.

Then, LED mounting is performed on the first and second electrode patterns 53a and 54a via flip chip bonding. First, as shown in FIG. 5f, solder bumps B1 and B2 are placed on the first and second electrode patterns 53a and 54a to which high power LED bonding electrodes are to be connected. Then, as shown in FIG. 5e, a high power LED 55 is mounted on the electrode patterns 53a and 54a so that bonding electrodes (not shown) of the high power LED 55 are connected to the solder bumps B1 and B2, respectively. Preferably, fluorescent material capable of converting light generated from the LED into different wavelength light may be applied to the surface of the LED 55.

In addition, the cavity of the upper board 52 may be filled with transparent resin or fluid 58 as shown in FIG. 5h to protect the LED 55. Then, as shown in FIG. 5i, a transparent lens structure 59 is mounted on the upper board 52, and the transparent resin or fluid 58 can be mixed with the fluorescent material which can convert the wavelength of light generated from the LED.

This process is an illustrative example of providing the two conductive via holes of vertical connection structures, in which more conductive via holes can be formed if necessary. For example, at least two conductive via holes can be used as vertical connection structures for connecting the first electrode pattern to the first bottom electrode.

FIG. 6 is a perspective view illustrating a lower board 61 having at least two conductive via holes according to an embodiment of the invention.

Referring to FIG. 6, the lower board 61 applicable to the invention is depicted. The lower board 61 has a heat radiation member 66. The lower board 61 also has five first via holes 63′ and five second via holes 64′, which are exposed from the top surface of the lower board 61 and arranged opposite positions around the heat radiation member 66. This embodiment has an advantage that a sufficient conductive area can be realized between the electrode patterns to be formed in the top and the bottom electrodes to be formed in the underside. In particular, this embodiment comprises a structure suitable to a high power LED having a plurality of electrodes, and permits the flow of electric current by massive amount.

It is also possible to provide only one conductive via hole and utilize the heat radiation member as a vertical connection structure for the other electrode as in the above embodiment shown in FIG. 4. This purpose can be easily realized through a modification in which only one conductive via hole is formed in the procedures shown in FIGS. 5a and 5b and both the second electrode pattern and the second bottom electrode are connected to the heat radiation member.

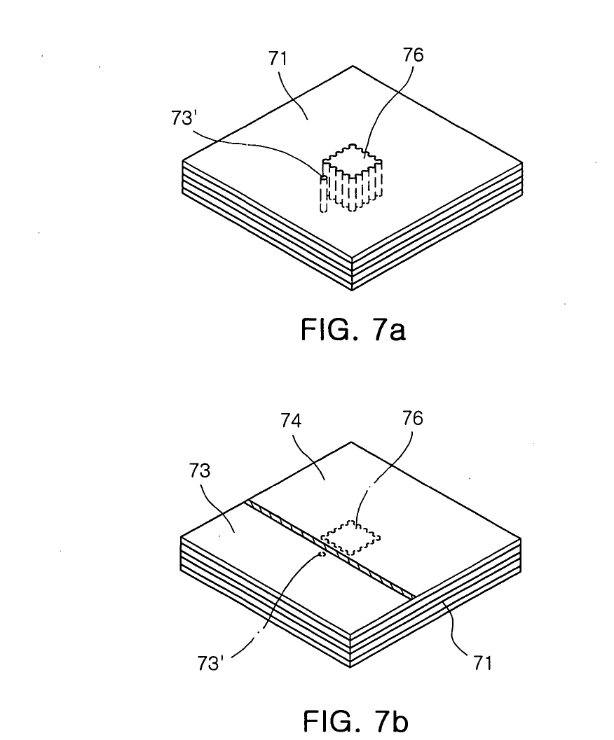

FIGS. 7a and 7b are perspective views illustrating a heat radiation member structure according to the invention. The embodiment shown in FIGS. 7a and 7b is an example of heat radiation member which can be stably fixed to the lower board.

Referring to FIG. 7a, a lower board 71 applicable to the invention is depicted. The lower board 71 can be adopted to the embodiment having a conductive via hole and a heat radiation member as shown in FIG. 4. As a consequence, one bottom electrode 73 is connected to a conductive via hole 73′ and the other bottom electrode 74 is connected to a heat radiation member 76 as shown in FIG. 7b

The heat radiation member 76 formed in the lower board 71 has a roughened face. Since the heat radiation member 76 of the invention has a large sectional area, there is a risk that it may escape out of the lower board 71. In order to prevent undesired escape, at least one face of the heat radiation member may be roughened horizontally. Alternatively, if the lower board is of a plurality of sheets or layers, the heat radiation member may be roughened vertically by imparting different sizes of cavity regions to the respective sheets and filling metal paste into the cavity regions.

While the present invention has been described with reference to the particular illustrative embodiments and the accompanying drawings, it is not to be limited thereto but will be defined by the appended claims. It is to be appreciated that those skilled in the art can substitute, change or modify the embodiments into various forms without departing from the scope and spirit of the present invention.

As set forth above, the present invention replaces wire bonding with flip chip bonding to simplify the overall structure as well as facilitate its fabrication process, and utilizes the insulation layer provided with the electrodes for flip chip bonding to realize the large-sized heat radiation member thereby remarkably enhancing heat radiation effect.

1. An LED package comprising:
a lower board having a heat radiation member formed in an LED mounting area and filled with conductive material and at least one via hole formed around the heat radiation member;
first and second bottom electrodes formed in the underside of the lower board and connected to the heat radiation member and the at least one conductive via hole, respectively;
an insulation layer formed on the top of the lower board to cover at least the heat radiation member;
first and second electrode patterns formed on the insulation layer and connected to the first and second bottom electrodes through the at least one conductive via hole, respectively; and
an LED connected to the first and second electrode patterns.

2. The LED package according to claim 1, wherein the LED is connected to the first and second electrode patterns via flip chip bonding.

3. The LED package according to claim 1, wherein the at least one conductive via hole comprises first and second conductive via holes arranged in opposite positions around the heat radiation member, and
wherein the first and second electrode patterns are connected to the first and second bottom electrodes through the first and second conductive via holes, respectively.

4. The LED package according to claim 3, wherein the first and second conductive via holes are provided in plurality, respectively.

5. The LED package according to claim 1, wherein the first electrode pattern is connected to the first bottom electrode via the at least one conductive via hole, and the second electrode pattern is connected to the second bottom electrode via the heat radiation member.

6. The LED package according to claim 1, wherein one of the first and second electrodes is leaded to the heat radiation member.

7. The LED package according to claim 1, wherein the heat radiation member has a sectional area matching at least 50% of that of the LED.

8. The LED package according to claim 1, wherein the heat radiation member has a sectional area larger than that of the LED.

9. The LED package according to claim 1, wherein the insulation layer has a thickness of about 100 μm or less. 10.

10. The LED package according to claim 1, further comprising an upper board formed on the lower board to surround the LED.

11. The LED package according to claim 10, wherein the upper board has a reflector provided in an inside wall portion surrounding the LED.

12. The LED package according to claim 10, further comprising a transparent lens structure provided on the upper board.

13. The LED package according to claim 1, wherein the heat radiation member formed in the lower board has faces, at least one of the faces being horizontally or vertically roughened.

14. A fabrication method of LED packages comprising the following methods of:
preparing a lower board having a heat radiation member formed in an LED mounting area filled with conductive material and an at least one conductive via hole formed around the heat radiation member;
forming an insulation layer on the top of the lower board to cover at least the heat radiation member;
forming first and second bottom electrodes in the underside of the lower board to be connected to the heat radiation member or the at least one conductive via hole;
forming first and second electrode patterns on the insulation layer to be connected to the first and second bottom electrodes through the heat radiation member or the at least one conductive via hole, respectively; and
mounting an LED to be connected to the first and second electrode patterns.

15. The fabrication method of LED packages according to claim 14, wherein the LED is connected to the first and second electrode patterns via flip chip bonding.

16. The fabrication method of LED packages according to claim 14, wherein the lower board preparation step provides the lower board having the heat radiation member and first and second conductive via holes which are arranged in opposite positions around the heat radiation member, and
wherein the first and second electrode patterns are connected to the first and second bottom electrodes through the first and second conductive via holes, respectively.

17. The fabrication method of LED packages according to claim 16, wherein the first and second conductive via holes are provided in plurality, respectively.

18. The fabrication method of LED packages according to claim 14, wherein the first electrode pattern is connected to the first bottom electrode through the conductive via hole, and the second electrode pattern is connected to the second bottom electrode through the heat radiation member.

19. The fabrication method of LED packages according to claim 14, wherein one of the first and second bottom electrodes is leaded to the heat radiation member.

20. The fabrication method of LED packages according to claim 14, wherein the heat radiation member has a sectional area matching at least 50% of that of the LED.

21. The fabrication method of LED packages according to claim 14, wherein the heat radiation member has a sectional area larger than that of the LED.

22. The fabrication method of LED packages according to claim 14, wherein the insulation layer has a thickness of about 100 μm or less.

23. The fabrication method of LED packages according to claim 13, further comprising mounting an upper board on the lower board to surround the LED.

24. The fabrication method of LED packages according to claim 23, wherein the upper board mounting step mounts the upper board having a reflector which is provided in an inside wall portion surrounding the LED.

25. The fabrication method of LED packages according to claim 23, further comprising the step of mounting a transparent lens structure on the upper board.

26. The fabrication method of LED packages according to claim 13, wherein the lower board preparation step roughens horizontally or vertically at least one wall of the heat radiation member of the lower board.
